(19) United States
(12) Patent Application Publication
(10) Pub. No.: US 2026/0096170 A1
(43) Pub. Date: Apr. 2, 2026

(54) SEMICONDUCTOR STRUCTURE AND MANUFACTURING METHOD THEREOF

(71) Applicant: Taiwan Semiconductor Manufacturing Co., Ltd., Hsinchu (TW)

(72) Inventors: Cheng-I Lin, Hsinchu (TW); Shu-Han Chen, Hsinchu (TW); Hao-Ming Tang, Taipei City (TW); Tsung-Da Lin, Hsinchu (TW); Chi On Chui, Hsinchu (TW)

(21) Appl. No.: 18/904,809

(22) Filed: Oct. 2, 2024

(51) Int. Cl. H01L 29/66; H01L 29/06; H01L 29/423; H01L 29/775; H01L 29/786

(52) U.S. Cl. CPC H10D 64/018; H10D 30/014; H10D 30/43; H10D 30/6735; H10D 30/6757; H10D 62/121; H10D 64/017; H10D 30/6736

(57) ABSTRACT

In an embodiment, a method of forming a semiconductor device is described that includes forming an opening to a stack of nanostructures, wherein sidewalls of the opening are provided by a gate spacer and an inner spacer. The method may further include applying an oxidizing plasma to the stack of nanostructures in the opening and the surfaces of the gate spacer and the inner spacer providing the sidewalls for the opening. In some embodiments, the oxidizing plasma forms a uniform thickness oxide surface on the stack of nanostructures in the opening and the surfaces of the gate spacer and the inner spacer. The method may further includes forming a high-k gate dielectric on the uniform thickness oxide surface on the stack of nanostructures in the opening and the surfaces of the gate spacer and the inner spacer, and forming a gate electrode on the high-k gate dielectric.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B, 6A, 6B, 7A, 7B, 7C, 8A, 8B, 9A, 9B, 10A, 10B, 10C, 10D, 11A, 11B, 11C, 11D, 12A, 12B, 13A, 13B, 14A, 14B, 15A, 15B, 15C, 15D, 15E, 15F, 17A, 17B, 17C, 17D, 17E, 17F, 18A, 18B, 18C, 18D, 18E, 18F, 19A, 19B, 19C, 20A, 20B, and 20C are cross-sectional views of intermediate stages in the manufacturing of nano-FETs, in accordance with some embodiments.

FIG. 16 illustrates an example of an inductively coupled plasma system in cross sectional view, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, methods and structures are described for spacer treatments and interfacial layer formation in stacked nanostructure devices. For example, in some embodiments of the described methods, the spacer treatment and the interfacial layer formation on the nanostructures are performed simultaneously, in which the spacer treatment and interfacial layer formation treatment includes radical oxidation. In some embodiments, the radical oxidation spacer treatment may be applied to gate spacers and/or inner spacers within the nanostructure stack of a device including nanostructure channels and a gate all around (GAA) gate structure. In some embodiments, the plasma oxidation process provides a uniform radical oxidation of the spacers. In some embodiments, the plasma oxidation process provides a non-uniform oxidation resulting in the formation of V-shaped spatially oxidized spacers.

In some embodiments, when the plasma oxidation process applied to the spacers is performed simultaneously with interfacial layer formation on the nanostructures, the methods described herein can reduce parasitic capacitance and enhance integrity of the interfacial layer. In some embodiments, reducing the parasitic capacitance can increase the alternating circuit (AC) performance for device circuit operation. Further, the oxidation method for forming the interfacial layer can increase reliability of the device.

Embodiments are described below in a particular context, a die comprising nano-FETs. Various embodiments may be applied, however, to dies comprising other types of transistors (e.g., stacking transistors, or the like) in lieu of or in combination with the nano-FETs.

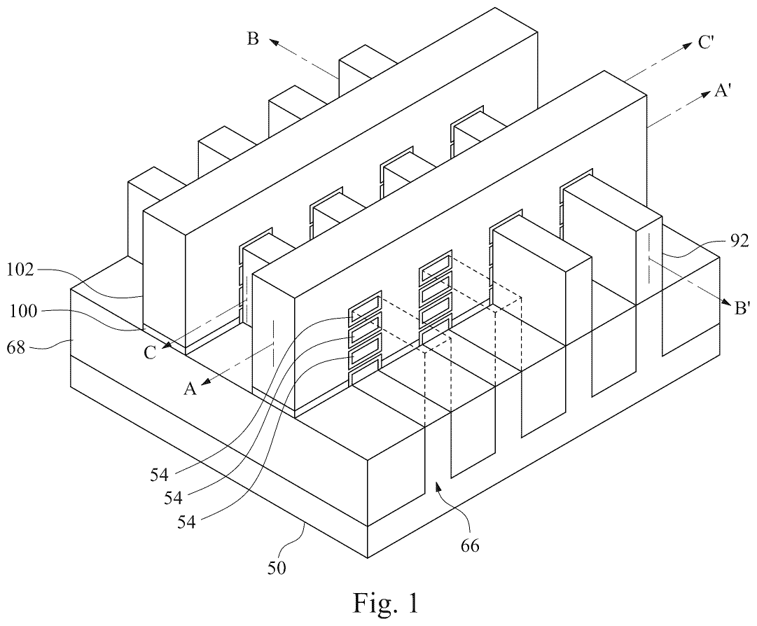

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. STI regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

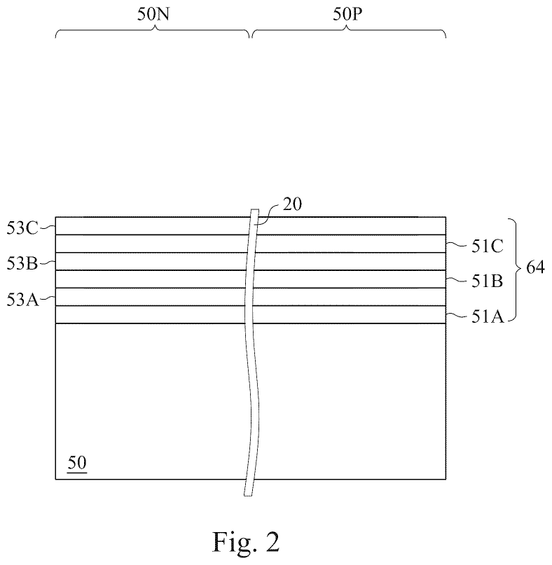

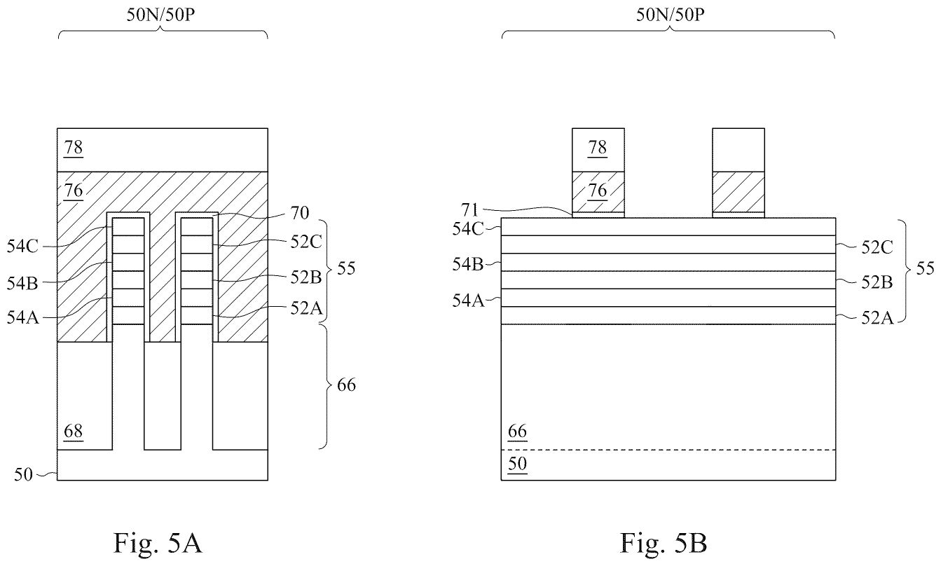

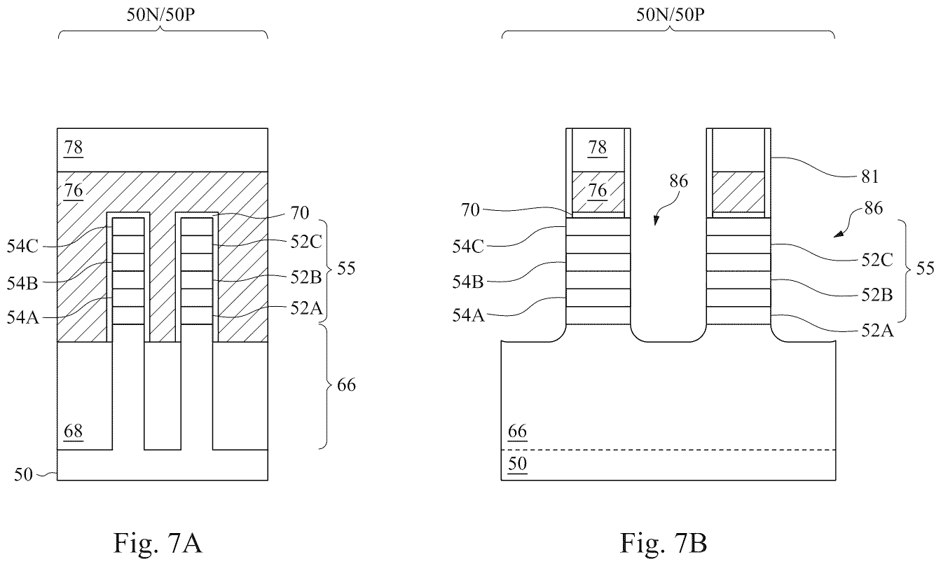

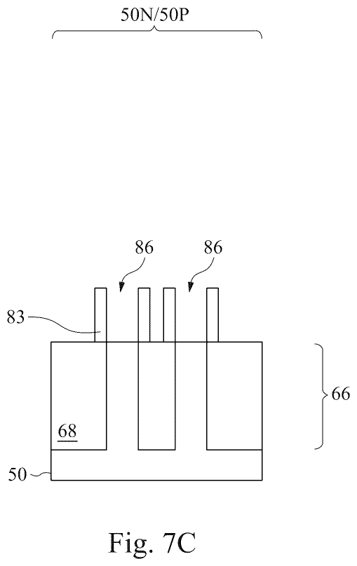

FIGS. 2 through 20C are cross-sectional views of intermediate stages in the manufacturing of nano-FETs, in accordance with some embodiments. FIGS. 2 through 5A, 6A, 7A, 8A, 9A, 10A, 11A, 12A, 13A, 14A, 15A, 15C, 15E, 17A, 17C, 17E, 18A, 18C, 18E, 19A and 20A illustrate reference cross-section A-A′ illustrated in FIG. 1. FIGS. 5B, 6B, 7B, 8B, 9B, 10B, 10C, 10D, 11B, 12B, 13B, 14B, 15B, 15D, 15F, 17B, 17D, 17C, 17F, 18B, 18D, 18F, 19B, and 20B illustrate reference cross-section B-B′ illustrated in FIG. 1. FIGS. 7C, 11C, 11D, 13C, 19C, 20C, and 21C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

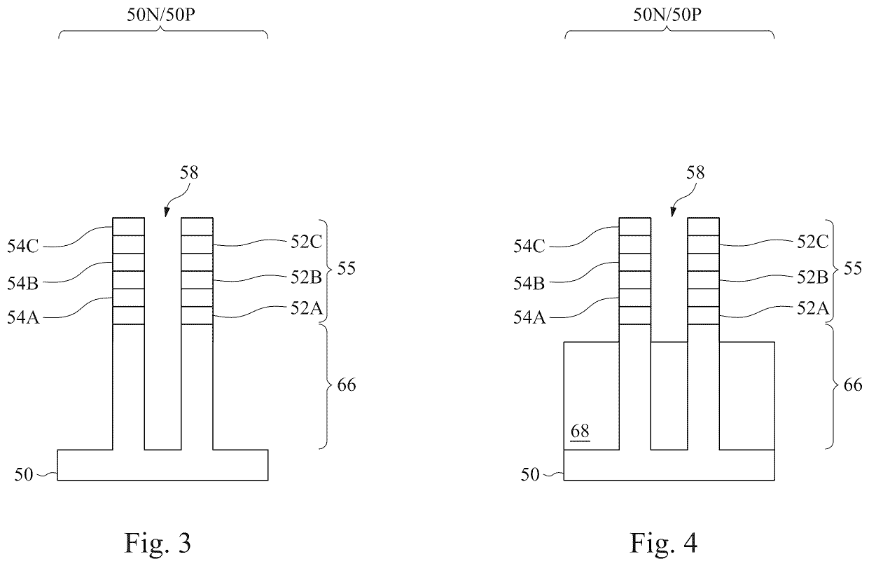

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in an embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

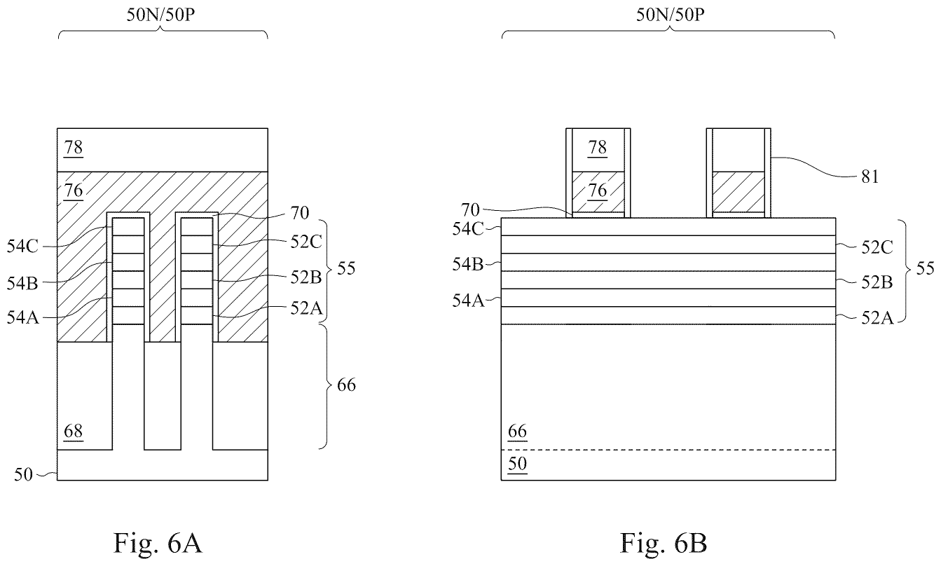

In FIGS. 6A and 6B, gate spacers 81 are formed over the nanostructures 55 and the STI regions 68, on exposed sidewalls of the masks 78 (if present), the dummy gates 76, and the dummy dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

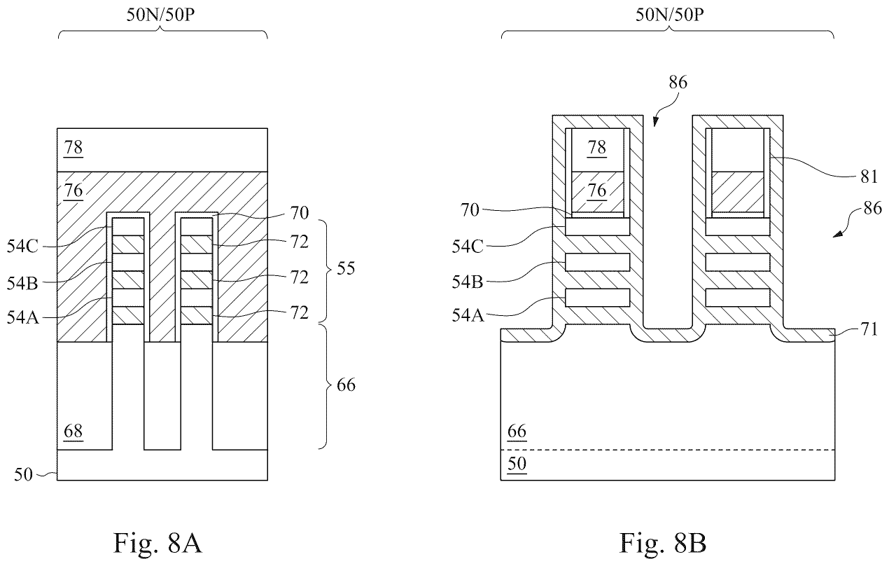

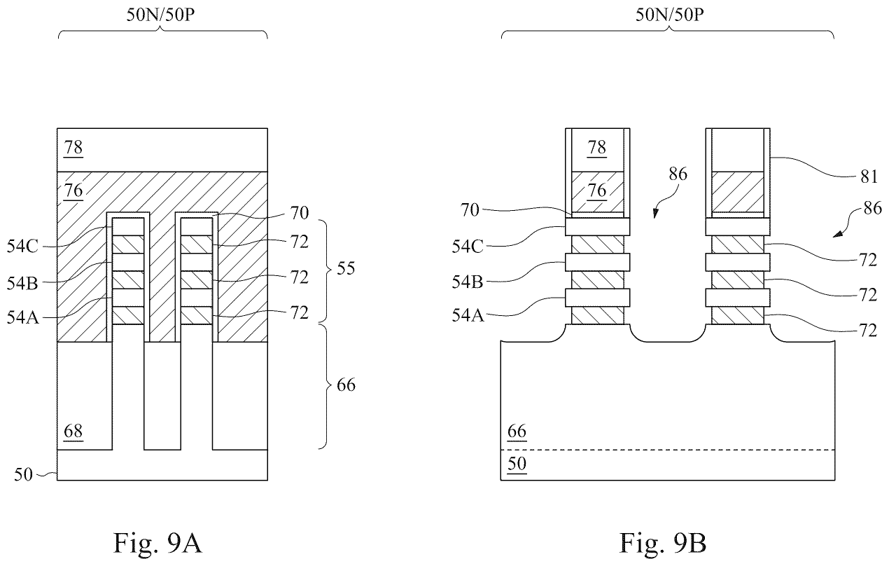

In FIGS. 8A-9B, the first nanostructures 52 are replaced with a sacrificial material 72 (also referred to as disposable oxide interposers (DOI) 72). Replacing the first nanostructures 52 may include etching away the first nanostructures 52 using a suitable etch process, such as an isotropic etch process, that is performed through the first recesses 86 as illustrated by FIGS. 8A-9B. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH4OH), or the like may be used to remove the first nanostructures 52.

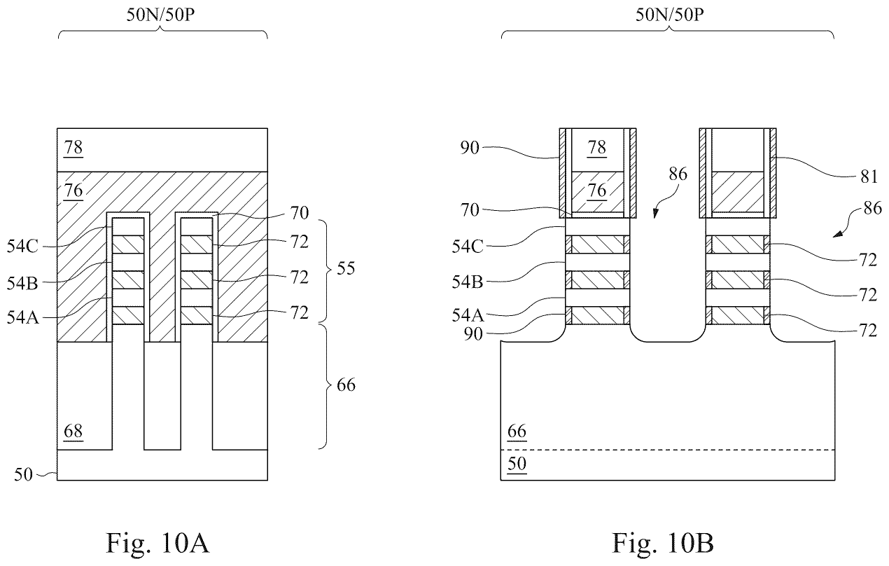

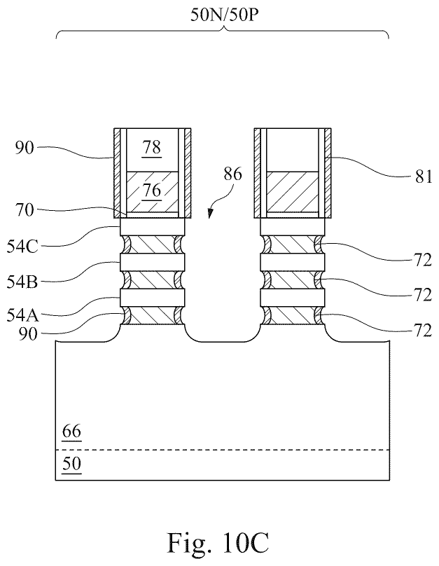

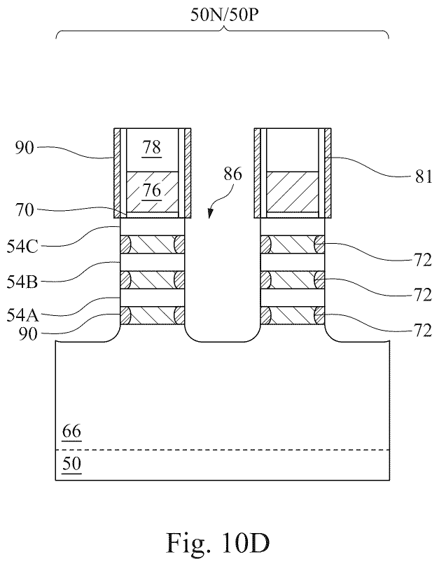

Subsequently, a sacrificial material layer 71 is deposited in the recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., SiO2), or the like that can be selectively etched from the second nanostructures 54. In FIGS. 9A-9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 9B, the sidewalls may be concave or convex (see e.g., FIG. 10C).

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the recesses 86 on the sidewalls of the sacrificial material 72. The inner spacers 90 act as isolation features between subsequently formed source/drain regions and a gate structure. As will be discussed in greater detail below, source/drain regions will be formed in the recesses 86, while the sacrificial material 72 will be replaced with corresponding gate structures. The inner spacers 90 may also be used to prevent damage to subsequently formed source/drain regions by subsequent etching processes, such as etching processes used to form gate structures. In some embodiments, a portion of the inner spacer 90 may extend onto the sidewall of the gate spacer 81.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. As an example, FIG. 10C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material 72 are concave, outer sidewalls of the inner spacers 90 are straight, and the inner spacers 90 are flush with sidewalls of the second nanostructures 54. Further, in some embodiments, a portion of the inner spacer 90 may extend onto the sidewall of the gate spacer 81, as depicted in the supplied figures.

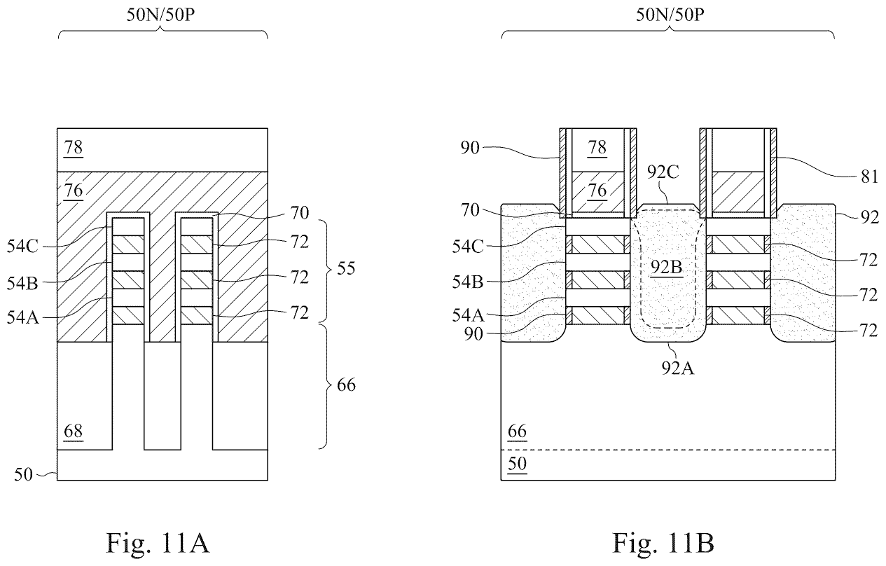

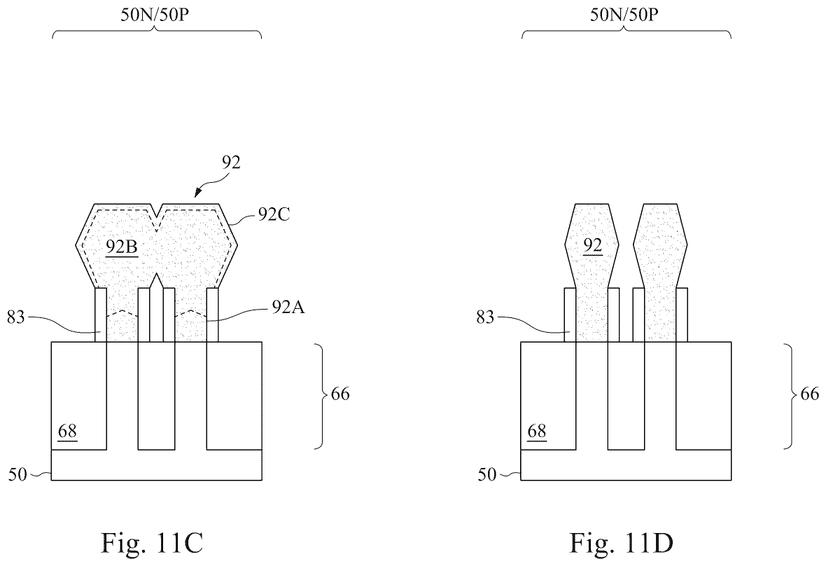

In FIGS. 11A-11D, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11C. In other embodiments, adjacent epitaxial source/drain regions 92 remain separated after the epitaxy process is completed as illustrated by FIG. 11D. In the embodiments illustrated in FIGS. 11C and 11D, the fin spacers 83 may be formed on top surfaces of the STI regions 68. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

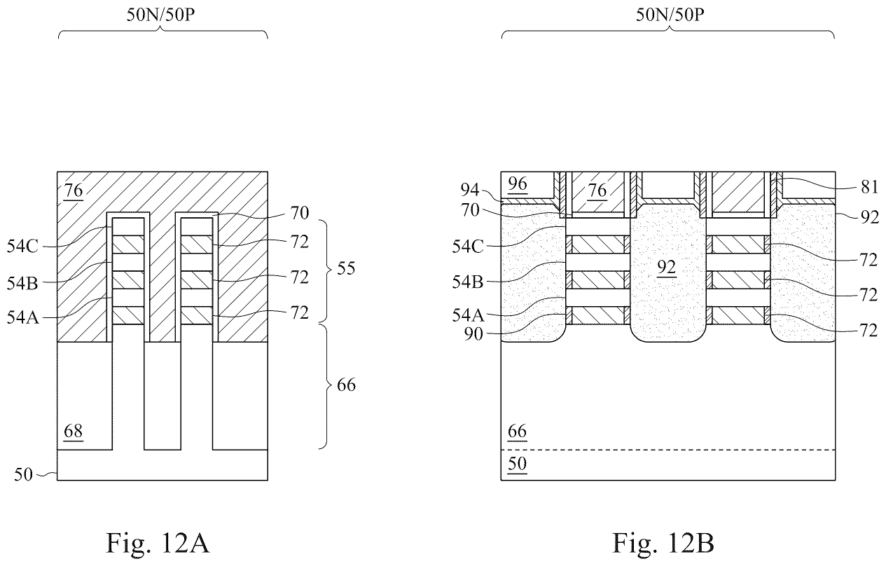

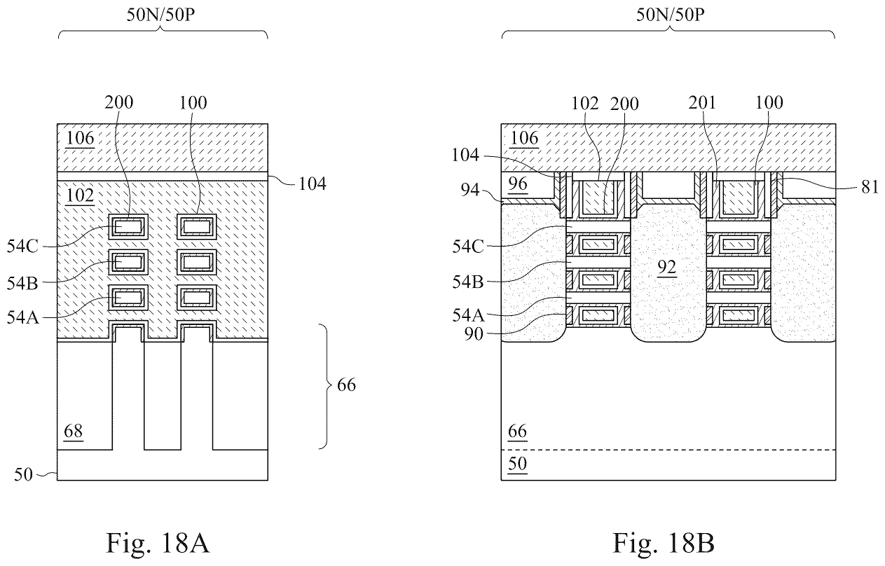

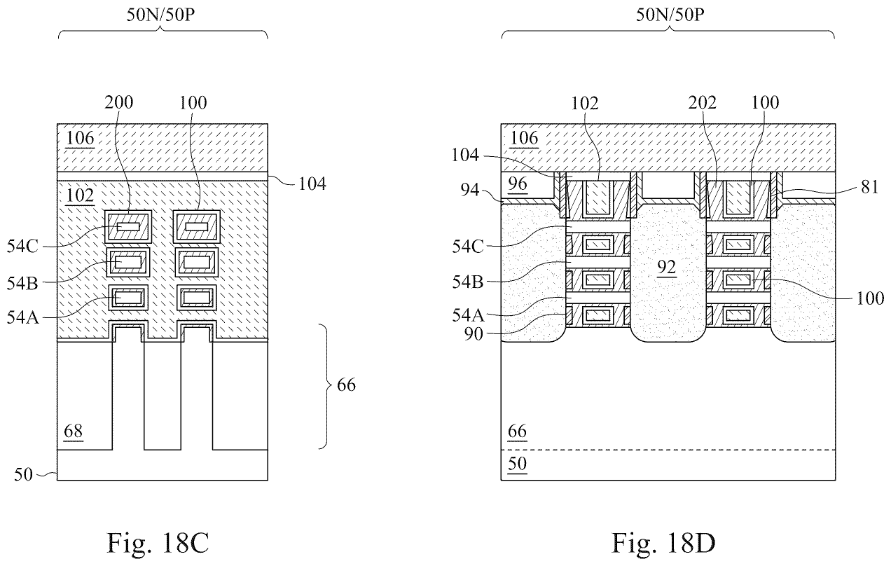

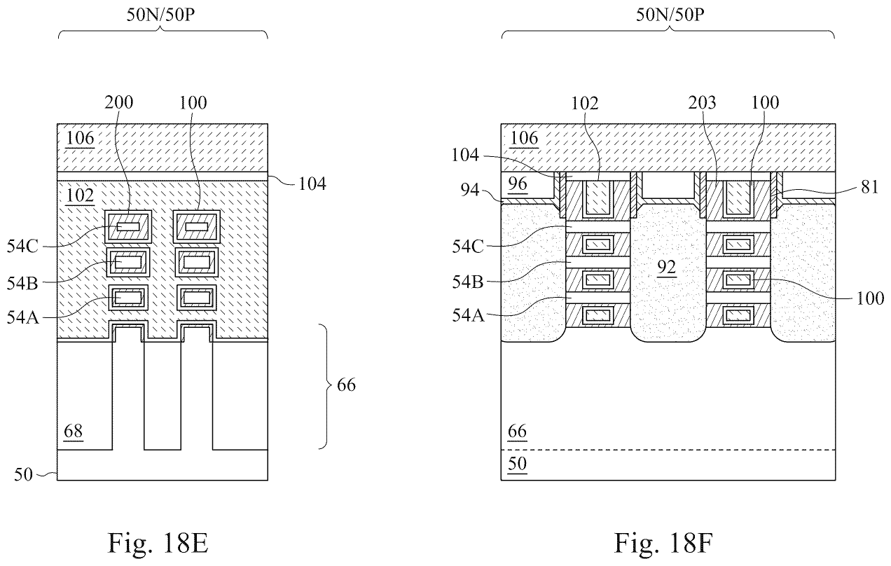

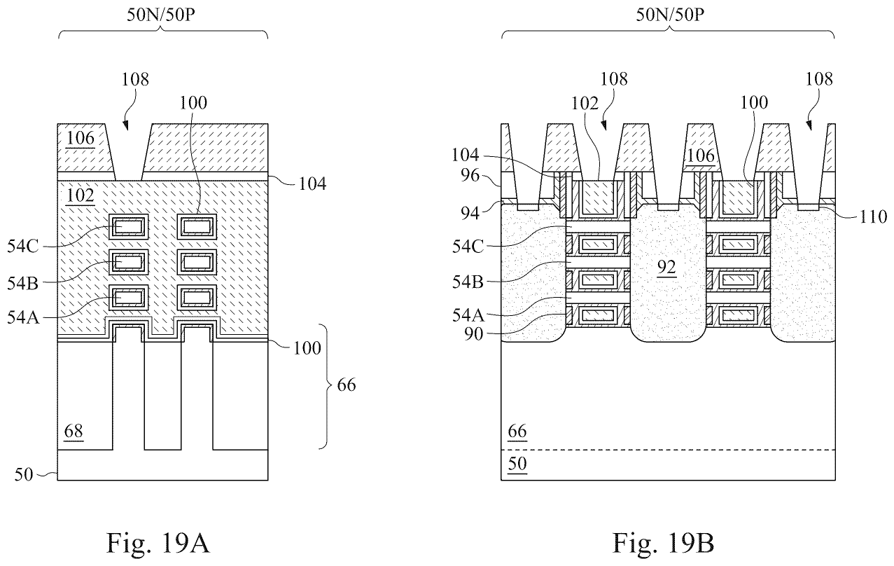

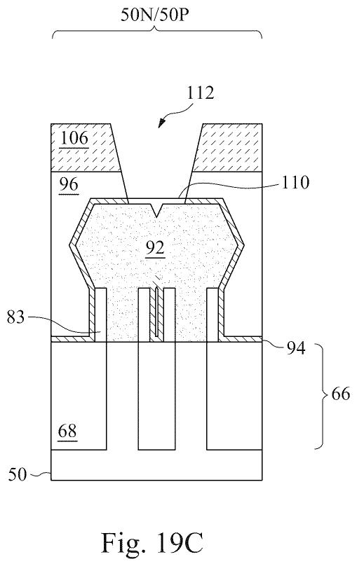

In FIGS. 12A and 12B, a first interlayer dielectric (ILD) 96 is deposited over the structure illustrated in FIGS. 18A and 19B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

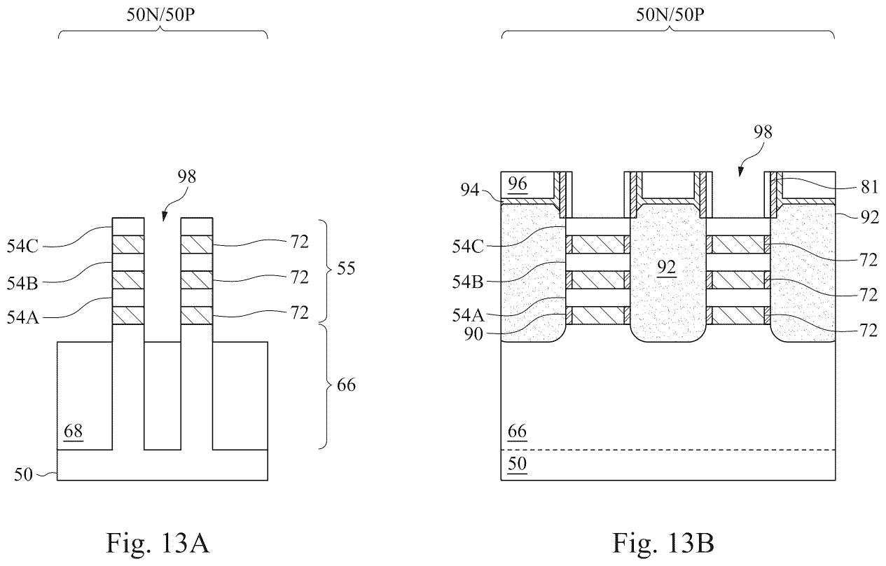

In FIGS. 13A and 13B, the dummy gates 76, and the masks 78 if present, are removed in one or more etching steps, so that second recesses 98 are formed. Portions of the dummy gate dielectrics 70 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

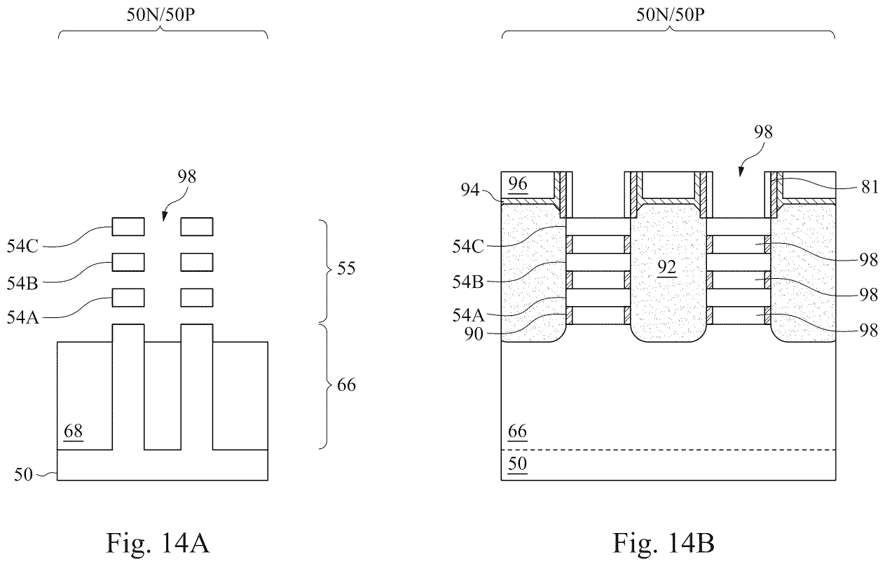

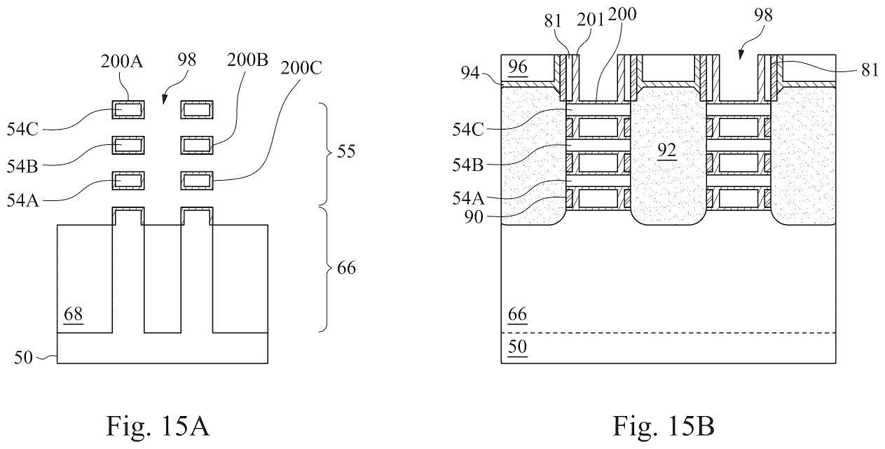

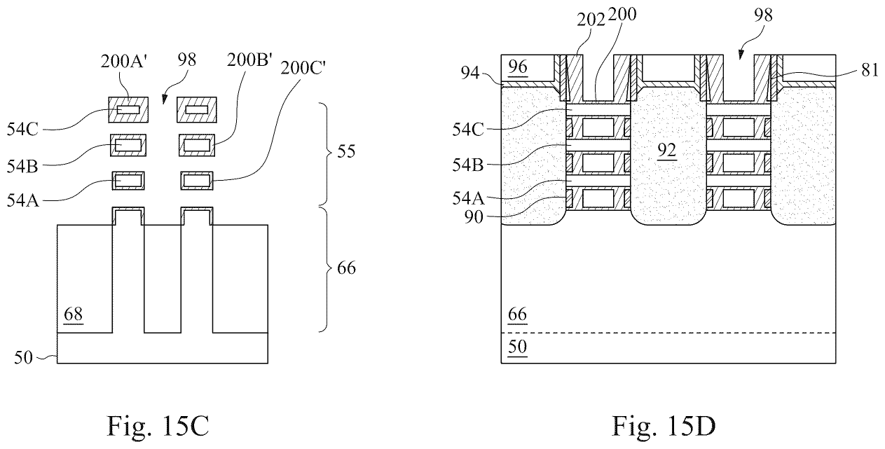

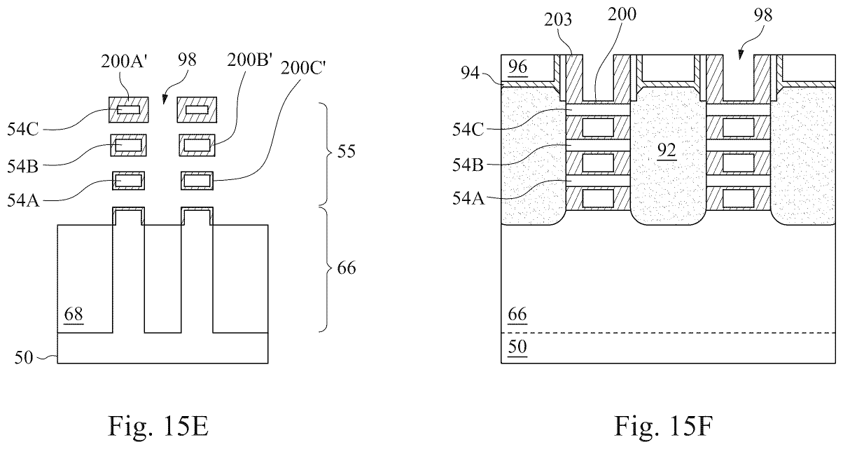

In FIGS. 14A and 14B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 15C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

FIGS. 15A-15F illustrate some embodiments of radical plasma oxidation for spacer treatment, e.g., treatment of the inner spacers 90 and the gate spacers 81, and interfacial layer 200 formation on the nanostructures 54A, 54B, 54C. The plasma oxidation spacer treatment and the interfacial layer 200 formation can reduce parasitic capacitance and boost the AC performance for device circuit operation. Furthermore, in some embodiments, radical oxidation can increase the interfacial layer 200 oxide integrity, which can increase device reliability.

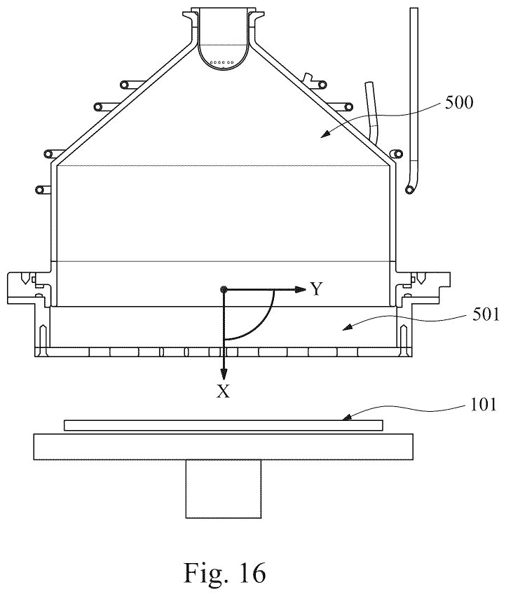

FIGS. 15A-15B illustrate using a uniform radical plasma oxidation for spacer treatment, e.g., gate spacer 81 and inner spacer 90 treatment, and interfacial layer (IL) 200 formation on the nanostructures 54A, 54B, 54C. In some embodiments, the gate spacer 91 and the inner spacer 90 may be composed of a nitride containing dielectric. In some examples, the inner spacer 90 and the gate spacer 81 can be composed of a dielectric that includes SiOCN, Si3N4, SiC, SiCN, or combinations thereof. In some embodiments, to reduce parasitic capacitance, a high-k dielectric material may be formed on surfaces of the inner spacer 90 and the gate spacer 81 that are exposed by removing the dummy gates 76. To form the high-k dielectric material, an oxide surface is advantageous. However, in some embodiments, the nitrogen concentration of the inner spacer 90 and the gate spacer 81 may be significant enough to result in an anti-oxidation performance. In some embodiments, the exposed spacer surfaces, e.g., the exposed surfaces of the gate spacer 81 and the inner spacer 90, are oxidized using an inductively coupled plasma (inductively coupled plasma) system 500 (see FIG. 16) that can generate O2 plasma or a combination of Ar and O2 plasma.

FIG. 16 illustrates an example of an inductively coupled plasma system 500. In some embodiments, an inductively coupled plasma (ICP) is generated by an ICP plasma system 500 by coupling the energy from a RF generator into a suitable gas via a magnetic field that is induced through a two or three turn, water-cooled copper coil. In some examples, the RF energy is normally supplied at a frequency of 27.12 MHz, delivering forward power at between 500 W and 2000 W. In some examples, two gas flows, usually containing argon (Ar), flow in a tangential manner through the outer tubes of a concentric, three-tube quartz torch that is placed axially in the copper coil. The outer and intermediate gases flow tangentially (i.e., they swirl around as they pass through the torch), so the plasma is continually revolving and has a ‘weak spot’ at the center of its base, through which the inner gas flow, containing the sample for producing oxidizing radicals e.g., oxygen, can be introduced. In some embodiments, a condition of O* radical (condition of radical plasma oxidation) generation is a temperature ranging from 200° C. to about 600° C. If the temperature is too high, it the plasma of oxygen radicals can produce an oxide layer that is too thick for being suitable for an interfacial layer 200, and the process may be difficult to control. If the temperature is too low, the energy may be too weak to produce enough oxide for basic electrical requirements, and therefore leakage may be likely to occur.

In some embodiments, a spark is used to seed the oxygen gas with electrons, which then accelerate in the magnetic field and reach energies sufficient to ionize gaseous atoms, e.g., radicals of oxygen and OH, in the field. Subsequent collisions with other gaseous atoms cause further ionization, and so on to form a self-sustaining plasma.

The plasma produced in the ICP plasma system 500, e.g., plasma of oxidizing radicals may be passed through a collimator 501 onto a deposition substrate 101. In some embodiments, the collimator 501 can remove any ions from the generated plasma that can damage the surface being coated. The deposition substrate 101 may include any of the structures depicted in FIGS. 15A-15F.

In some embodiment, the lifetime of the O* radical is 1000 times longer than the lifetime of a comparable O²⁺ ion. In some embodiments, the O* radical has longer lifetime, the O* radical can diffuse downward to achieve uniform oxidation.

In the embodiment depicted in FIGS. 15A and 15B, the gate spacers 81 and the inner spacers 90 are oxidized to provide a uniform thickness oxide surface 201 extending from an upper surface of the upper most gate spacers 81 to the lower most surface of the inner spacers 90. By uniform thickness it is meant that the thickness of the oxidized material, e.g., the uniform thickness oxide surface 201 formed on the gate spacer 81 and the inner spacer 90, is substantially the same along the entire length of the oxidized surface.

As noted, an interfacial layer 200 is formed on the nanostructures 54A, 54B, 54C at the same time as the oxidized surface on the spacers, e.g., gate spacer 81 and inner spacer 90, with the same oxidizing plasma of oxygen radicals. Referring to FIG. 15B, the oxidized surface for the interfacial layer 200A on the upper most nanostructure 54C has the same thickness as the oxidized surface for the interfacial layer 200C of the lower most nanostructure 54A. The nanostructure 54B between the upper and lower nanostructures 54C, 54A also has an oxidized surface for the interfacial layer 200B having the same thickness as the other oxidized nanostructures surfaces, e.g., interface layers 200A, 200C. It is noted that this example only depicts three nanostructures 54A, 54B, 54C, and it is not intended that the present disclosure be limited to only this example. Any number of nanostructures is suitable for use with the methods and structures described herein, with any number of interface layers. It is noted that the interface layer 200 and the uniform thickness oxide surface 201 on the gate spacer 81 and the inner spacer 80 can be silicon oxide having a low dielectric constant. However, the subsequently formed high-k dielectric constant will have a dielectric constant suitable for reducing parasitic capacitance. Further, for the embodiments depicted in FIGS. 15A-15B, the entirety of the gate spacer 81 and the inner spacer 80 is not consumed by the oxide surface produced by the oxygen radicals of the plasma.

In some examples, the uniform oxidation depicted in FIGS. 15A-15B have some advantages and benefits. For example, simultaneous formation of interfacial layer 200 and the spacer treatment can be easily integrated in a replacement gate process flow, e.g., gate last process flow. The uniform oxidation can provide a parasitic capacitance (Ceff) reduction for device AC operation. Additionally, a uniform interfacial layer 200 can be better for gate control. Interfacial layer integrity can provide increased reliability supporting an enlargement of the process window.

FIGS. 15C-15D depict another embodiment that employs oxygen ion plasm oxidation to produce a V-shaped spatially plasma oxidation surface 202 on the spacers, e.g., the gate spacer 81 and the inner spacer 90. The V-shaped spatially plasma oxidation surface 202 can reduce parasitic capacitance. Further, similar to the embodiments described with reference to FIGS. 15A-15B, the plasma oxidation can form an interfacial layer (IL) 200 on the nanostructures 54A, 54B, 54C simultaneously with forming the oxide surface of the spacers, e.g., the gate spacer 81 and the inner spacer 90. The interfacial layer 200 can be beneficial to oxide integrity for reliability.

Similar to the embodiments described in FIGS. 15A-15B, oxidized surfaces of the nanostructures 54A, 54B, 54C, the inner spacers 90 and the gate spacers 81 may be produced by an oxygen radical including inductively coupled plasma (ICP) that can be generated by the ICP plasma system 500 depicted in FIG. 16. In some embodiments, for oxygen (O) ion plasma oxidation, the lifetime of the O* radical is 1000 times longer than the lifetime of the O²⁺ ion. In some examples, since the O²⁺ ion has shorter lifetime, V-shape oxide can be formed. One process condition for producing a V-shaped spatially plasma oxidation surface 202 with an oxygen plasma using the ICP plasma system 5o0 is a temperature applied to the oxygen containing gas ranging from about 200° C. to about 600° C.

In the embodiment depicted in FIGS. 15C and 15D, the gate spacers 81 and the inner spacers 90 are oxidized to provide a V-shaped spatially plasma oxidation surface 202 extending from an upper surface of the upper most gate spacers 81 to the lower most surface of the inner spacers 90. The V-shaped spatially plasma oxidation surface 202 has a non-uniform thickness, e.g., a non-uniform thickness extending along the height of the V-shaped spatially plasma oxidation surface 202. More particularly, the V-shaped spatially plasma oxidation surface 202 formed on the gate spacers 81 and the inner spacers 90 has a greatest thickness, e.g., greatest width, at the uppermost portion of gate spacers 81. For example, the oxidation process to provide the V-shaped spatially plasma oxidation surface 202 may consume the entirety of the upper portion of the gate spacer 81. Further, the V-shaped spatially plasma oxidation surface 202 formed on the gate spacers 81 and the inner spacer 90 may have its smallest thickness, e.g., smallest with, at the base of the bottom most inner spacer 90.

As noted, an interfacial layer 200 is formed on the nanostructures 54A, 54B, 54C at the same time as the oxidized surface is formed on the spacers, e.g., gate spacer 81 and inner spacer 90, with the same oxidizing plasma of oxygen radicals. Referring to FIG. 15D, the oxidized surface for the interfacial layer 200A′ on the upper most nanostructure 54C has a greater thickness than the oxidized surface for the interfacial layer 200C′ of the lower most nanostructure 54A. The nanostructure 54B between the upper and lower nanostructures 54C, 54A has an oxidized surface for the interfacial layer 200B′ with a thickness that is less than the thickness of the upper most oxidized surface 200A′ and is greater than the thickness of the lower most oxidized surface 200C′. It is noted that this example only depicts three nanostructures 54A, 54B, 54C, and it is not intended that the present disclosure be limited to only this example. Any number of nanostructures is suitable for use with the methods and structures described herein, with any number of interface layers.

The gate spacer 81 and the inner spacer 80 can be silicon oxide having a low dielectric constant. However, the subsequently formed high-k dielectric constant will have a dielectric constant suitable for reducing parasitic capacitance. Further, for the embodiments depicted in FIGS. 15C-15D, the entirety of the gate spacer 81 and the inner spacer 80 does not need to be consumed by the oxide surface produced by the oxygen radicals of the plasma.

In some examples, the oxidation depicted in FIGS. 15C-15D have some advantages and benefits. For example, simultaneous formation of interfacial layer 200 and the spacer treatment can be easily integrated in a replacement gate process flow, e.g., gate last process flow. The V-shaped spatially plasma oxidation surface 202 can provide an aggressive parasitic capacitance Ceff reduction for device AC operation (e.g., more aggressive than the uniform oxidation depicted in FIGS. 5A-5B). Additionally, an interfacial layer 200 can be better for gate control. Interfacial layer integrity can provide increased reliability supporting an enlargement of the process window.

FIGS. 15E-15F depict another embodiment that employs oxygen ion plasma oxidation to fully consume the spacers, e.g., the inner spacer 90 and the gate spacer 81, with a plasma oxidation surface 203. The plasma oxidation surface 203 that fully consumes the inner spacer 90 and the gate spacer 81 can reduce parasitic capacitance. Further, similar to the embodiments described with reference to FIGS. 15A-15D, the plasma oxidation can form an interfacial layer (IL) 200 on the nanostructures 54A, 54B, 54C simultaneously with forming the oxide surface on the spacers, e.g., the gate spacer 81 and the inner spacer 90. The interfacial layer 200 can be beneficial to oxide integrity for reliability.

Similar to the embodiments described in FIGS. 15A-15D, oxidized surfaces of the nanostructures 54A, 54B, 54C, the inner spacers 90 and the gate spacers 81 may be produced by an oxygen radical including inductively coupled plasma (ICP) that can be generated by the ICP plasma system 500 depicted in FIG. 16. In some embodiments, for oxygen (O) ion plasma oxidation, the lifetime of the O* radical is 1000 times longer than the lifetime of the O²⁺ ion. In some examples, because the O²⁺ ion has a shorter lifetime, a plasma oxidation surface 203 that fully consumes the inner spacer 90 and the gate spacer 81 can be formed. In addition, for producing a plasma oxidation surface 203 that fully consumes the inner spacer 90 and the gate spacer 81 sufficient process time and pressure may be needed to fully convert the spacers to SiO2. For example, the process time for fully consuming the spacers may range from 1 minute to about 5 minutes. If the time is too short, the oxidation may be insufficient. If the time is too long, the oxidation may be excessive. For example, the pressure for fully consuming the spacers may range from about 0.1 Torr to about 4 Torr. If the pressure is too low, the ion/radical amount may not enough to oxidize the spacers. If the pressure is too high, the oxidation may be excessive.

Another process condition for producing a plasma oxidation surface 203 that fully consumes the inner spacer 90 and the gate spacer 81 using the ICP plasma system 5o0 is a temperature applied to the oxygen containing gas ranging from about 200° C. to about 600° C. In the embodiment depicted in FIGS. 15E and 15F, the gate spacers 81 and the inner spacers 90 are oxidized until fully consumed.

As noted, an interfacial layer 200 is formed on the nanostructures 54A, 54B, 54C at the same time as the oxidized surface on the spacers, e.g., gate spacer 81 and inner spacer 90, with the same oxidizing plasma of oxygen radicals. Referring to FIG. 15D, the oxidized surface for the interfacial layer 200A′ on the upper most nanostructure 54C has a greater thickness than the oxidized surface for the interfacial layer 200C′ of the lower most nanostructure 54A. The nanostructure 54B between the upper and lower nanostructures 54C, 54A has an oxidized surface for the interfacial layer 200B′ with a thickness that is less than the thickness of the upper most oxidized surface 200A′ and is greater than the thickness of the lower most oxidized surface 200C′. It is noted that this example only depicts three nanostructures 54A, 54B, 54C, and it is not intended that the present disclosure be limited to only this example. Any number of nanostructures is suitable for use with the methods and structures described herein, with any number of interface layers. It is noted that the interface layer 200 and the uniform thickness oxide surface 201 on the gate spacer 81 and the inner spacer 80 can be silicon oxide having a low dielectric constant. However, the subsequently formed high-k dielectric constant will have a dielectric constant suitable for reducing parasitic capacitance.

In some examples, the oxidation depicted in FIGS. 15E-15F have some advantages and benefits. For example, simultaneous formation of interfacial layer 200 and the spacer treatment can be easily integrated in a replacement gate process flow, e.g., gate last process flow. The plasma oxidation surface 203 that fully consumes the inner spacer 90 and the gate spacer 81 can provide an aggressive parasitic capacitance Ceff reduction for device AC operation (e.g., more aggressive than the V-shaped spatially plasma oxidation surface 202 depicted in FIGS. 5C-5D). Additionally, the interfacial layer 200 can be better for gate control. Interfacial layer integrity can provide increased reliability supporting an enlargement of the process window.

In some embodiments, following the plasma oxidation described with reference to FIGS. 15A-15F, a wet clean process may be applied to the oxidized surfaces. The wet clean process can increase the concentration of OH groups on the oxidized surfaces. In an embodiment, the wet clean process may include a standard clean 1 (SC1) at a temperature ranging from 30° C. to 90° C. In one example, the standard clean 1 (SC1) composition includes 5 parts deionized water, 1 part ammonia water (29% NH₃) and 1 part hydrogen peroxide (30% H₂O₂). In some embodiments, after the wet clean, the oxidized surfaces have −OH group for the subsequent ALD process for depositing high-k dielectrics.

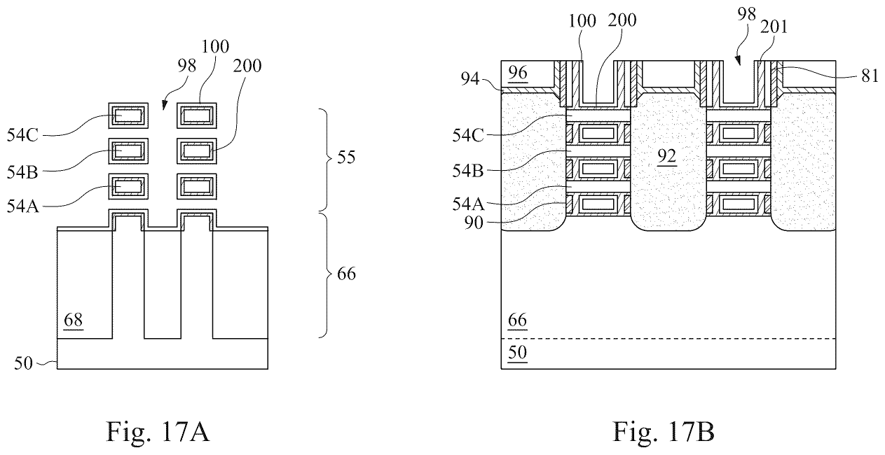

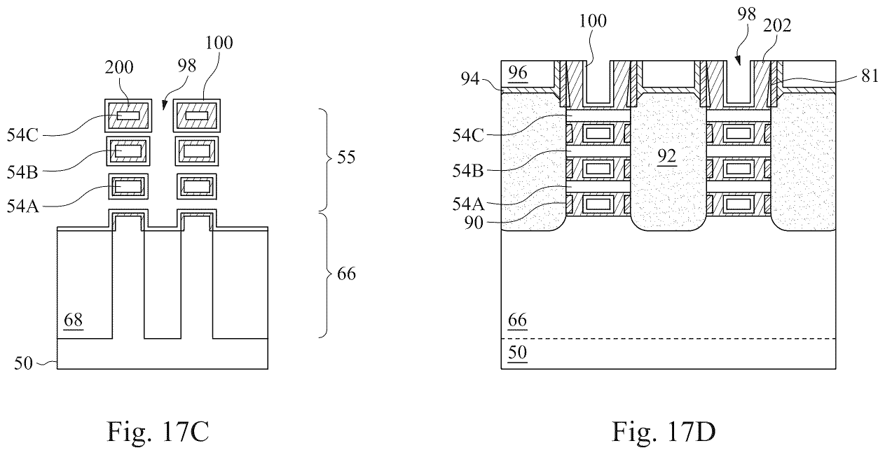

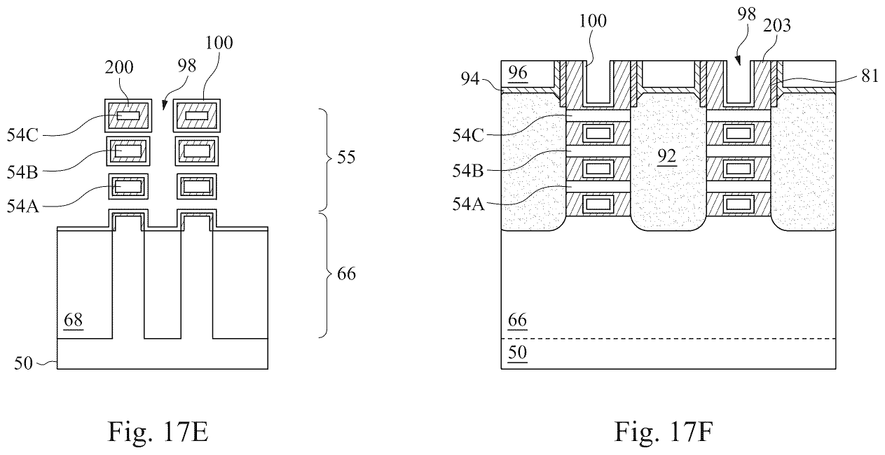

In FIGS. 17A-17F, high-k gate dielectric layers 100 are formed for replacement gates. FIGS. 17A-17B depict forming the high-k dielectric layers 100 on the interfacial layer 200 and the uniform thickness oxide surface 201 of the spacers depicted in FIGS. 15A-15B. FIGS. 17C-17D depict forming the high-k dielectric layers 100 on the interfacial layer 200 and the V-shaped spatially plasma oxidation surface 202 of the spacers depicted in FIGS. 15C-15D. FIGS. 17E-17F depict forming the high-k dielectric layers 100 on the interfacial layer 200 and the plasma oxidation surface 203 that fully consumes the inner spacer and the gate spacer 81 of the structure depicted in FIGS. 15E-15F.

The high-k gate dielectric layers 100 are deposited conformally in the second recesses 98 on the oxidized surfaces of the spacers, e.g., gate spacers 81 and inner spacer 90, and on the oxidized surfaces of the interfacial layer 200. The gate dielectric layers 100 may also be deposited on top surfaces of the first ILD 96, the CESL 94, the gate spacers 81, and the STI regions 68.

In accordance with some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. In one example, the high-k gate dielectric layers 100 are composed of hafnium oxide. The structure of the high-k gate dielectric layers 100 may be the same or different in the n-type region 50N and the p-type region 50P. The formation methods of the gate dielectric layers 100 may include atomic layer deposition (ALD). However, other deposition methods may also be employed for forming the high-k gate dielectric layers 100 including molecular-beam deposition (MBD), PECVD, and the like.

FIGS. 18A-18F illustrate gate electrodes 102 being deposited over the gate dielectric layers 100, respectively, and fill the remaining portions of the second recesses 98. FIGS. 18A-18B depict forming gate electrodes 102 on the high-k gate dielectric 100 depicted in FIGS. 17A-17B. FIGS. 18C-18D depict forming the gate electrodes 102 on the high-k gate dielectric 100 depicted in FIGS. 17C-17D. FIGS. 18E-18F depict forming the gate electrode 102 on the high-k gate dielectric 100 of the structure depicted in FIGS. 17E-17F.

The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 18A-18E, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

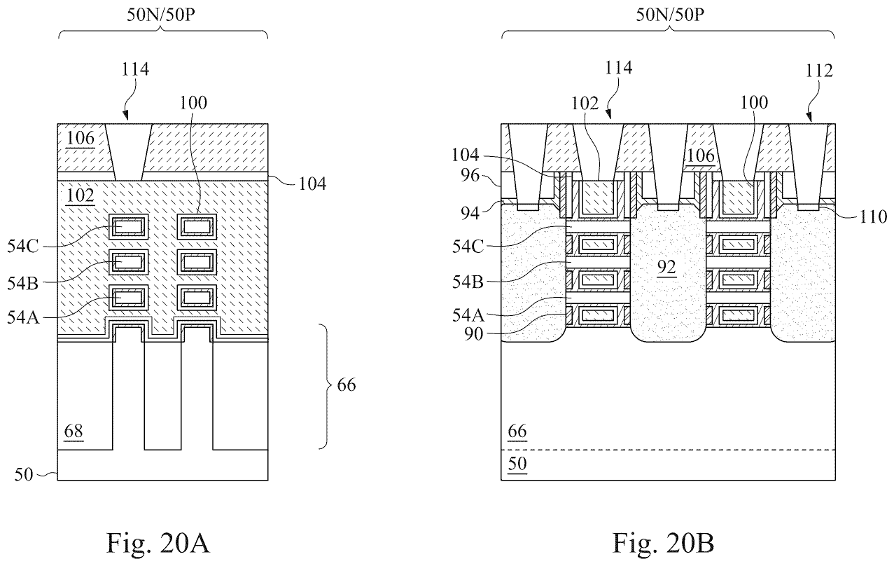

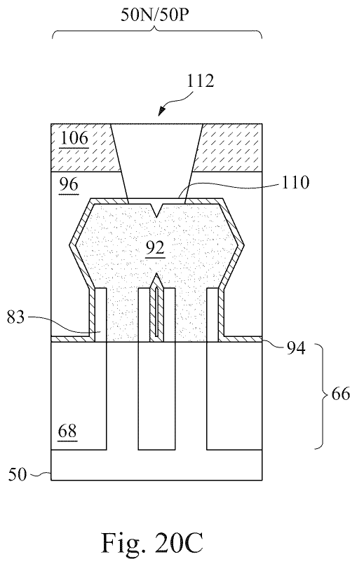

The gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 20A-20C) penetrate through the gate mask 104 to contact the top surface of the recessed gate electrodes 102.

As further illustrated by FIGS. 18A-18F, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 19A-19C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 20A-20C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

In various embodiments, methods and structures are described for spacer treatments and interfacial layer formation in stacked nanosheet devices. For example, in some embodiments of the described methods, the spacer treatment and the interfacial layer formation on the nanostructures are performed simultaneously, in which the spacer treatment and interfacial layer formation treatment includes radical oxidation. In some embodiments, the radical oxidation spacer treatment may be applied to gate spacers and/or spacers within the nanosheet stack of a device including nanosheet channels and a gate all around (GAA) gate structure. In some embodiments, uniform radical oxidation of the spacers, or non-uniform oxidation resulting in the formation of V-shaped spatially oxidized spacers, when performed simultaneously with interfacial layer formation, e.g., oxide formation, on the nanostructures can reduce parasitic capacitance and enhance integrity of the interfacial layer. In some embodiments, reducing the parasitic capacitance can increase the alternating circuit (AC) performance for device circuit operation. Further, the oxidation method for forming the interfacial layer can increase reliability of the device.

In an embodiment, a method of forming a semiconductor device comprising:
forming an opening to a stack of nanostructures, wherein sidewalls of the opening are provided by a gate spacer and an inner spacer; applying an oxidizing plasma to the stack of nanostructures in the opening and surfaces of the gate spacer and the inner spacer providing the sidewalls for the opening, wherein the oxidizing plasma forms a uniform thickness oxide surface on the stack of nanostructures in the opening and forms the uniform thickness oxide surface on the surfaces of the gate spacer and the inner spacer; forming a high-k gate dielectric on the uniform thickness oxide surface on the stack of nanostructures in the opening and the surfaces of the gate spacer and the inner spacer; and forming a gate electrode on the high-k gate dielectric. In an embodiment, forming the opening to the stack of nanostructures comprises removing a replacement gate structure. In an embodiment, applying the oxidizing plasma consumes only a portion of the gate spacer and the inner spacer to form the uniform thickness oxide surface, wherein a remaining portion of the gate spacer and the inner spacer is free of oxide. In an embodiment, a wet clean process is applied to the uniform thickness oxide surface to increase a concentration of -OH groups on the uniform thickness oxide surface. In an embodiment, the uniform thickness oxide surface has a uniform thickness along its entire height from an upper surface of the gate spacer to a lower surface of the inner spacer. In an embodiment, the uniform thickness oxide surface has a same thickness on each nanostructure of the stack on nanostructures. In an embodiment, the high-k gate dielectric is formed using atomic layer deposition (ALD). In an embodiment, the method includes forming source/drain regions contacting the stack of nanostructures on opposing sides of the gate electrode.

In another embodiment, a method of forming a semiconductor device comprising: forming an opening to a stack of nanostructures, wherein sidewalls of the opening are provided by a gate spacer and an inner spacer; applying an oxidizing plasma to the stack of nanostructures in the opening and surfaces of the gate spacer and the inner spacer providing the sidewalls for the opening, wherein the oxidizing plasma forms a non-uniform thickness oxide surface on the stack of nanostructures in the opening; forming a high-k gate dielectric on the non-uniform thickness oxide surface on the stack of nanostructures in the opening; and forming a gate electrode on the high-k gate dielectric. In an embodiment, forming the opening to the stack of nanostructures includes removing a replacement gate structure. In an embodiment, applying the oxidizing plasma consumes an entirety of a material of the gate spacer and the inner spacer. In an embodiment, the non-uniform thickness oxide surface on the nanostructures includes a first thickness oxide surface on an upper nanostructure in the stack of nanostructures, and a second thickness oxide surface of a lower nanostructure in the stack of nanostructures, wherein the first thickness oxide surface has a greater thickness than the second thickness oxide surface. In an embodiment, the non-uniform thickness oxide surface is formed on the surfaces of the gate spacer and the inner spacer. In an embodiment, the non-uniform thickness oxide surface has a first width at an upper surface of the gate spacer and a second width at a lower surface of the inner spacer, the first width being greater than the second width. In an embodiment, the method further includes a wet clean process applied to the uniform thickness oxide surface to increase a concentration of -OH groups on the uniform thickness oxide surface. In an embodiment, the high-k gate dielectric is formed using atomic layer deposition (ALD). In an embodiment, the method further includes forming source/drain regions contacting the stack of nanostructures on opposing sides of the gate electrode.

In yet another embodiment, semiconductor device comprising: a stack of nanostructures; a gate structure including a high-k gate dielectric on a first portion of the stack of nanostructures and a gate electrode on the high-k gate dielectric; source/drain regions on opposing sides of the gate structure; and a spacer on sidewalls of the gate electrode and separating the gate electrode and the source/drain regions in a space between separated nanostructures in the stack of nanostructures, wherein the spacer comprises an oxide surface having a first width at an upper surface of the stack of nanostructures, and a second width at a lower surface of the stack of nanostructures, wherein the first width is greater than the second width. In an embodiment, the spacer includes a nitride containing material. In an embodiment, the stack of nanostructures includes a first interface layer having a first thickness for a first nanostructure at an upper surface of the stack of nanostructures and a second interface layer having a second thickness for a second nanostructure at a lower surface of the stack of nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device comprising:
forming an opening to a stack of nanostructures, wherein sidewalls of the opening are provided by a gate spacer and an inner spacer;
applying an oxidizing plasma to the stack of nanostructures in the opening and surfaces of the gate spacer and the inner spacer providing the sidewalls for the opening, wherein the oxidizing plasma forms a uniform thickness oxide surface on the stack of nanostructures in the opening and forms the uniform thickness oxide surface on the surfaces of the gate spacer and the inner space;
forming a high-k gate dielectric on the uniform thickness oxide surface on the stack of nanostructures in the opening and the surfaces of the gate spacer and the inner spacer; and
forming a gate electrode on the high-k gate dielectric.

2. The method of claim 1, wherein the forming of the opening to the stack of nanostructures comprises removing a replacement gate structure.

3. The method of claim 1, wherein the applying the oxidizing plasma consumes only a portion of the gate spacer and the inner spacer to form the uniform thickness oxide surface, wherein a remaining portion of the gate spacer and the inner spacer is free of the uniform thickness oxide surface.

4. The method of claim 1, further comprising a wet clean process applied to the uniform thickness oxide surface.

5. The method of claim 1, wherein the uniform thickness oxide surface has a uniform thickness along its entire height from an upper surface of the gate spacer to a lower surface of the inner spacer.

6. The method of claim 1, wherein the uniform thickness oxide surface has a same thickness on each nanostructure of the stack on nanostructures.

7. The method of claim 1, wherein the high-k gate dielectric is formed using atomic layer deposition (ALD).

8. The method of claim 1, further comprising source/drain regions contacting the stack of nanostructures on opposing sides of the gate electrode.

9. A method of forming a semiconductor device comprising:
forming an opening to a stack of nanostructures, wherein sidewalls of the opening are provided by a gate spacer and an inner spacer;
applying an oxidizing plasma to the stack of nanostructures in the opening and surfaces of the gate spacer and the inner spacer providing the sidewalls for the opening, wherein the oxidizing plasma forms a non-uniform thickness oxide surface on the stack of nanostructures in the opening;
forming a high-k gate dielectric on the non-uniform thickness oxide surface on the stack of nanostructures in the opening; and
forming a gate electrode on the high-k gate dielectric.

10. The method of claim 9, wherein the forming of the opening to the stack of nanostructures comprises removing a replacement gate structure.

11. The method of claim 9, wherein the applying the oxidizing plasma consumes an entirety of a material of the gate spacer and the inner spacer.

12. The method of claim 11, wherein the non-uniform thickness oxide surface on the nanostructures includes a first thickness oxide surface on an upper nanostructure in the stack of nanostructures, and a second thickness oxide surface of a lower nanostructure in the stack of nanostructures, wherein the first thickness oxide surface has a greater thickness than the second thickness oxide surface.

13. The method of claim 9, wherein the non-uniform thickness oxide surface is formed on the surfaces of the gate spacer and the inner spacer.

14. The method of claim 13, wherein the non-uniform thickness oxide surface has a first width at an upper surface of the gate spacer and a second width at a lower surface of the inner spacer, the first width being greater than the second width.

15. The method of claim 9, further comprising a wet clean process applied to the non-uniform thickness oxide surface.

16. The method of claim 9, wherein the high-k gate dielectric is formed using atomic layer deposition (ALD).

17. The method of claim 9, further comprising source/drain regions contacting the stack of nanostructures on opposing sides of the gate electrode.

18. A semiconductor device comprising:
a stack of nanostructures;
a gate structure including a high-k gate dielectric on a first portion of the stack of nanostructures and a gate electrode on the high-k gate dielectric;
source/drain regions on opposing sides of the gate structure; and
a spacer on sidewalls of the gate electrode 102 and separating the gate electrode 102 and the source/drain regions in a space between separated nanostructures in the stack of nanostructures, wherein the spacer comprises an oxide surface having a first width at an upper surface of the stack of nanostructures, and a second width at a lower surface of the stack of nanostructures, wherein the first width is greater than the second width.

19. The semiconductor device of claim 18, wherein the spacer comprises a nitride containing material.

20. The semiconductor device of claim 18, wherein the stack of nanostructures includes an first interface layer having a first thickness for a first nanostructure at an upper surface of the stack of nanostructures and a second interface layer having a second thickness for a second nanostructure at a lower surface of the stack of nanostructures.
